(19) United States
(12) Patent Application Publication
(10) Pub. No.: US 2025/0105208 A1
(43) Pub. Date: Mar. 27, 2025

(54) MODULE AND METHOD FOR MANUFACTURING SAME

(71) Applicant: UltraMemory Inc., Tokyo (JP)

(72) Inventors: Shigeru NAKAHARA, Tokyo (JP); Fumitake OKUTSU, Tokyo (JP); Masatoshi HASEGAWA, Tokyo (JP)

(21) Appl. No.: 18/704,311

(22) PCT Filed: Nov. 12, 2021
(86) PCT No.: PCT/JP2021/041735

§ 371 Date: Apr. 24, 2024

(51) Int. Cl. H01L 25/065; H01L 23/00; H01L 23/31; H01L 23/367; H10B 80/00

(52) U.S. Cl. CPC H01L 25/0652; H01L 23/3677; H01L 24/16; H10B 80/00; H01L 23/3128; H01L 24/13; H01L 2224/13023; H01L 2224/1357; H01L 2224/16148; H01L 2224/16225; H01L 2225/06513; H01L 2225/06517; H01L 2924/1436

(57) ABSTRACT

A module including a stack of a plurality of dies and a package substrate. The stack including a main die, two intermediate dies disposed between the package substrate and the main die, a sub die being juxtaposed with the main die, and a connecting component electrically connecting the package substrate to the main die and the sub die. An other intermediate die of the two intermediate dies is disposed in a state in which an entirety of the circuit surface of the other intermediate die faces the circuit surface of the main die, and the one intermediate die is disposed astride an end portion of the circuit surface of the main die and an end portion of the circuit surface of the sub die in a state in which the circuit surface of the one intermediate die faces the end portions.

### TECHNICAL FIELD

The present invention relates to a module and a method for manufacturing the module.

### BACKGROUND ART

Conventionally, a volatile memory (RAM) such as a dynamic random access memory (DRAM) has been known as a storage device. The DRAM is required to have a large capacity such that it can support high performance of an arithmetic unit (hereinafter referred to as a logic chip) and an increase in a volume of data. For this reason, attempts have been made to increase the capacity by way of miniaturization of the memory (memory cell array, memory chip) and planar addition of cells. On the other hand, this type of increase in capacity is reaching its limit because of the miniaturization resulting in susceptibility to noise, an increase in die area, and other factors.

Therefore, in recent years, a technique for achieving a large capacity by way of a three-dimensional (3D) structure that is formed by stacking a plurality of planar memories has been developed. Furthermore, in response to an increase in a volume of data to be handled, attempts have been made to increase the speed of data communication between chips (a logic chip and a memory chip) (for example, see Patent Documents 1 to 3).

### CITATION LIST

### Patent Document

Patent Document 1: US Patent Application, Publication No. 2008/0128882
Patent Document 2: US Patent Application, Publication No. 2015/0145116
Patent Document 3: US Patent Application, Publication No. 2015/0255411

### DISCLOSURE OF THE INVENTION

### Problems to be Solved by the Invention

Patent Document 1 discloses a semiconductor module including an intermediate substrate that has a recess formed in an upper portion of the intermediate substrate and plugs penetrating through the intermediate substrate. A large chip is disposed over one surface of the intermediate substrate, and a package substrate is disposed over the other surface. A small chip is disposed at the position of the recess. The large chip is electrically connected to the package substrate and the small chip via the plugs. However, using the intermediate substrate having plugs leads to a high cost.

Patent Document 2 discloses a semiconductor module that is produced by forming a seed layer on a substrate, and forming low pillars in regions other than a resist. Furthermore, in a second photolithography step, pillars are spliced to some of the low pillars to thereby form high pillars. Thereafter, the seed layer is removed, and two chips are stacked and connected to the pillars. However, forming the pillars having different heights on the substrate requires two photolithography steps, which leads to a high cost.

Patent Document 3 discloses a semiconductor module that is produced by disposing one die on a portion of a package substrate from which a solder resist has been removed, and disposing the other die so as to overlap with the one die. The other die is connected to the package substrate and the one die. Since the other die is connected in the same step in which the package substrate and the one die are connected, it is necessary to control the heights with increased accuracy, which leads to a high cost. In addition, in the case where there is variation in heights, the yield may be reduced.

The present invention has been achieved in view of the above-described disadvantages, and it is an object of the present invention to provide a module in which a plurality of different types of chips are integrated at low cost, and a method for manufacturing such a module.

### Means for Solving the Problems

The present invention is directed to a module including a stack of a plurality of dies, and a package substrate. The stack includes a main die having a circuit surface and disposed with the circuit surface facing a main surface of the package substrate, at least one intermediate die disposed between the package substrate and the main die and having a circuit surface facing the circuit surface of the main die, a sub die having a circuit surface and disposed with the circuit surface facing the circuit surface of the at least one intermediate die, the sub die being juxtaposed with the main die in a direction intersecting with a thickness direction of the main die, and a connecting component electrically connecting the package substrate to a region of the circuit surface of the main die and a region of the circuit surface of the sub die, the regions not overlapping with the intermediate die. At least one of the at least one intermediate die is disposed astride an end portion of the circuit surface of the main die and an end portion of the circuit surface of the sub die in a state in which the circuit surface of the at least one of the at least one intermediate die faces the end portions.

Preferably, the module further includes a relief layer disposed between the at least one intermediate die and the package substrate and configured to relieve stress between the package substrate and the at least one intermediate die.

The connecting component preferably has a multilayer connection structure.

Preferably, any one of the main die, the intermediate die, and the sub die is a stacked memory.

The circuit surface of the main die preferably includes, in a region adjacent to a region connected to the intermediate die, a power supply circuit that boosts or steps down a voltage of power to be supplied to the intermediate die.

The main die and the sub die preferably are supplied power to each other via the intermediate die disposed astride the main die and sub die.

Preferably, the sub die is a power supply plate that supplies power to the intermediate die disposed astride the main die and sub die.

Furthermore, the present invention is directed to a method for manufacturing a module including a stack of a plurality of dies. The method includes: a connecting component disposing step including disposing a connecting component configured to establish electrical connection, on a circuit surface of a main die; an intermediate die disposing step including disposing a plurality of intermediate dies over the circuit surface of the main die such that circuit surfaces of the intermediate dies face the circuit surface of the main die; a package substrate disposing step including disposing a package substrate having, on one surface thereof, a relief layer for relieving stress disposed at a position overlapping with at least one intermediate die of the plurality of intermediate dies such that the one surface of the package substrate faces the main die and the intermediate dies, and bringing the relief layer into contact with the at least one intermediate die; and a sub die disposing step including disposing a sub die such that a circuit surface of the sub die faces the circuit surface of the at least one intermediate die and the one surface of the package substrate. In the intermediate die disposing step, the at least one intermediate die is disposed such that an end portion of the at least one intermediate die protrudes from an end of the main die in a direction intersecting with a thickness direction.

Preferably, the connecting component disposing step includes a main-side connecting component disposing step including disposing one connection terminal on the circuit surface of the main die, and a substrate-side connection terminal disposing step including disposing an other connection terminal on the one surface of the package substrate.

Preferably, the intermediate die disposed astride the main die and the sub die is a memory die that relays communication between the main die and the sub die, and includes an interface circuit, a control and arbitration circuit, a memory control circuit, and a memory array.

Preferably, the intermediate die disposed astride the main die and the sub die is a stacked memory in which a logic die and a memory die are stacked.

Preferably, the main die and the sub die are arranged in a one-dimensional direction or a two-dimensional direction in a plan view, via the intermediate die disposed astride the main die and the sub die.

### Effects of the Invention

The present invention makes it possible to provide a module in which a plurality of different types of chips are integrated at low cost, and a method for manufacturing such a module.

### BRIEF DESCRIPTION OF THE DRAWINGS

FIG. 1 is a cross-sectional view illustrating a module according to a first embodiment of the present invention;

FIG. 2 is a cross-sectional view illustrating a process of manufacturing the module according to the first embodiment;

FIG. 3 is a cross-sectional view illustrating a process of manufacturing the module according to the first embodiment;

FIG. 4 is a cross-sectional view illustrating a process of manufacturing the module according to the first embodiment;

FIG. 5 is a cross-sectional view illustrating a process of manufacturing the module according to the first embodiment;

FIG. 6 is a cross-sectional view illustrating a process of manufacturing the module according to the first embodiment;

FIG. 7 is a cross-sectional view illustrating a process of manufacturing the module according to the first embodiment;

FIG. 8 is a cross-sectional view illustrating a module according to a second embodiment of the present invention;

FIG. 9 is a cross-sectional view illustrating a process of manufacturing the module according to the second embodiment;

FIG. 10 is a cross-sectional view illustrating a process of manufacturing the module according to the second embodiment;

FIG. 11 is a cross-sectional view illustrating a module according to a third embodiment of the present invention;

FIG. 12 is a cross-sectional view illustrating a module according to a fourth embodiment of the present invention;

FIG. 13 is a cross-sectional view illustrating a process of manufacturing the module according to the fourth embodiment;

FIG. 14 is a cross-sectional view illustrating a module according to the fourth embodiment;

FIG. 15 is a partial cross-sectional view illustrating a module according to a fifth embodiment of the present invention;

FIG. 16 is a partial cross-sectional view illustrating a module according to a sixth embodiment of the present invention; and

FIG. 17 is a plan view illustrating an example of an intermediate die of a module according to a modification.

### PREFERRED MODE FOR CARRYING OUT THE INVENTION

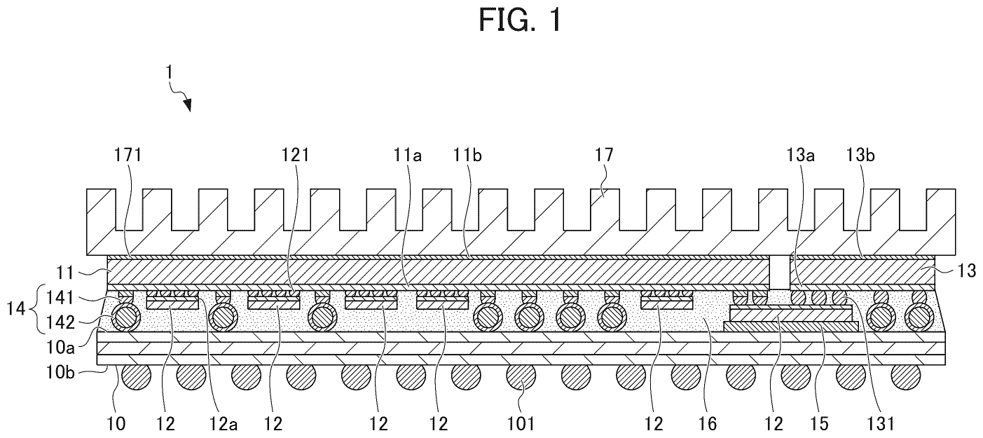

A module 1 and a method for manufacturing the module 1 according to each embodiment of the present invention will be described below with reference to FIGS. 1 to 17. First, an outline of the module 1 according to each embodiment will be described.

The module 1 according to each embodiment includes a plurality of different types of chips (dies) that are integrated. Thus, the module 1 is provided in which the plurality of chips are arranged over one package substrate 10. Since the plurality of chips have different sizes and thicknesses, it is necessary to arrange the plurality of chips over the package substrate 10 in consideration of the sizes and thicknesses. In particular, a circuit that electrically connects the plurality of chips needs to be built, and the circuit preferably has a configuration that leads to a high yield at lower cost. The following embodiments are each intended to provide the module 1 that achieves a high yield at a low cost.

### First Embodiment

Next, the module 1 according to a first embodiment of the present invention and a method for manufacturing the module 1 will be described with reference to FIGS. 1 to 7. The module 1 according to the first embodiment includes a stack of a plurality of dies. As illustrated in FIG. 1, the module 1 includes a package substrate 10, a main die 11, a plurality of intermediate dies 12, a sub die 13, connecting components 14, a relief layer 15, an underfill layer 16, and heat dissipation fins 17.

The package substrate 10 is, for example, an organic substrate. The package substrate 10 is a plate-shaped member having a rectangular shape in plan view. The package substrate 10 includes a circuit (not shown) therein. The package substrate 10 has surfaces 10a and 10b opposite to each other. Solder balls 101 for electrically connecting to a main substrate (not shown) are arranged on the surface 10b.

The main die 11 is, for example, a processor such as an MPU. The main die 11 is a plate-shaped member having a rectangular shape in plan view. The main die 11 has a smaller area than the package substrate 10 in plan view. The main die 11 has a circuit surface 11a on one surface thereof. The main die 11 is disposed with the circuit surface 11a facing the main surface 10a of the package substrate 10.

The intermediate die 12 includes at least one intermediate die 12. Preferably, the intermediate die 12 includes a plurality of the intermediate dies 12. The intermediate dies 12 include a stacked DRAM, an IF-IP, a stacked SRAM, a power supply module VRM, a coprocessor, etc. Each intermediate die 12 is a plate-shaped member having a rectangular shape in plan view. The intermediate dies 12 are disposed between the package substrate 10 and the main die 11 such that circuit surfaces 12a of the intermediate dies 12 face the circuit surface 11a of the main die 11. The intermediate dies 12 are electrically connected to the main die 11 via micro-bumps 121 or the like.

The sub die 13 is, for example, a power supply plate. The sub die 13 is a plate-shaped member having a rectangular shape in plan view. The sub die 13 has a circuit surface 13a and is disposed with the circuit surface facing the circuit surface 12a of at least one intermediate die 12. The sub die 13 is juxtaposed with the main die 11 in a direction intersecting with a thickness direction of the main die 11. In the present embodiment, the sub die 13 is electrically connected to the circuit surface 12a of the at least one intermediate die 12 via solder balls or the like. Solder balls 131 as an example of the connecting components 14 are arranged on the circuit surface 13a of the sub die 13.

The main die 11, the intermediate dies 12, and the sub die 13 described above are arranged such that at least one intermediate die 12 of the plurality of intermediate dies 12 is disposed astride an end portion of the circuit surface 11a of the main die 11 and an end portion of the circuit surface 13a of the sub die 13 in a state in which the circuit surface 12a of the at least one intermediate die 12 faces the end portions. In the present embodiment, for example, one intermediate die 12 is a stacked memory (stacked DRAM) and is disposed astride an end portion of the main die 11 and an end portion of the sub die 13 in a state in which the circuit surface 12a of the one intermediate die 12 faces the circuit surface 11a of the main die 11 and the circuit surface 13a of the sub die 13. The one intermediate die 12 is electrically connected to both the main die 11 and the sub die 13. In the present embodiment, the one intermediate die 12 is connected to the main die 11 via, for example, Cu pillars 141 each having a protruding portion coated with solder and forming part of the connecting components 14.

The connecting components 14 include, for example, a conductive material. The connecting components 14 electrically connect the package substrate 10 to regions belonging to the circuit surface of the main die 11 and not overlapping with the intermediate dies 12 and regions belonging to the circuit surface of the sub die 13 and not overlapping with the intermediate dies 12. The connecting components 14 have, for example, a multilayer connection structure. Specifically, the connecting components 14 include, for example, the Cu pillars 141 disposed on the circuit surface of the main die 11 and Cu core balls 142 disposed on the one surface 10a of the package substrate 10.

The relief layer 15 is, for example, a die-attaching material. The relief layer 15 is disposed between the at least one intermediate die 12 and the package substrate 10, and relieves stress between the package substrate 10 and the at least one intermediate die 12. In the present embodiment, the relief layer 15 is disposed between the stacked DRAM, which is the one of the intermediate dies 12, and the package substrate 10. In the present embodiment, the relief layer 15 may include a material having a high thermal conductivity.

The underfill layer 16 is, for example, an epoxy layer. The underfill layer 16 is interposed between the package substrate 10 and the main die 11. Furthermore, the underfill layer 16 is interposed between the package substrate 10 and the sub die 13. The underfill layer 16 is interposed between the main die 11 and the intermediate dies 12. The underfill layer 16 is interposed between the sub die 13 and the intermediate die 12.

The heat dissipation fins 17 include, for example, a metal material. The heat dissipation fins 17 have a larger area than the main die 11 and the sub die 13 in plan view. For example, the heat dissipation fins 17 are disposed, via a TIM 171, over exposed surfaces of the main die 11 and the sub die 13, which are opposite to the respective circuit surfaces.

According to the module 1 described above, power is supplied from the package substrate 10 to the main die 11 and the sub die 13 through the connecting components 14. Each intermediate die 12 connected to the main die 11 receives power from the main die 11. Each intermediate die 12 connected to the sub die 13 receives power from the sub die 13. The intermediate die 12 connected to the main die 11 and the sub die 13 receives power from both dies. This allows the plurality of dies to operate.

Next, a method for manufacturing the module 1 according to the present embodiment will be described. The method for manufacturing the module 1 includes a main die disposing step, a connecting component disposing step, an intermediate die disposing step, a relief layer disposing step, a package substrate disposing step, a sub die disposing step, a solder ball disposing step, and a heat dissipation fin disposing step.

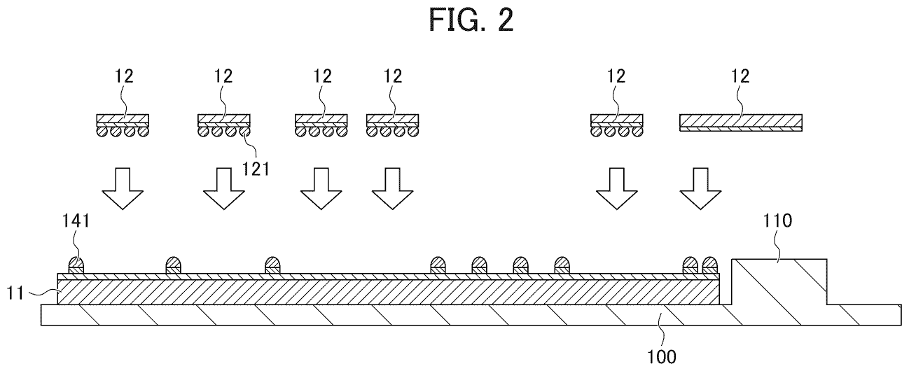

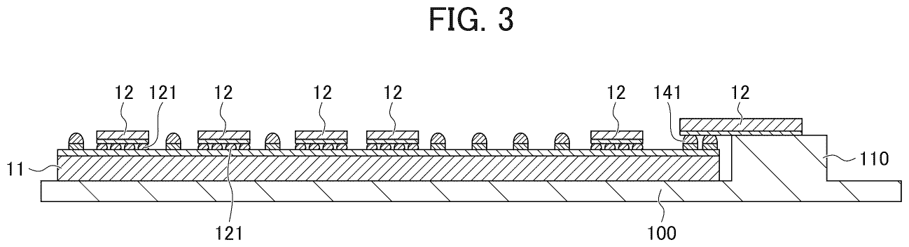

As illustrated in FIGS. 2 and 3, in the main die disposing step, the main die 11 is disposed on a mounting jig 100. In particular, the mounting jig 100, on which the main die 11 is disposed, has a pedestal portion 110 that is a protrusion formed at a position where the intermediate die 12 to be disposed astride end portions of the main die and the sub die is placed. The main die 11 is disposed at a position on the mounting jig 100 that does not overlap with the pedestal portion 110.

In the connecting component disposing step, the connecting components 14 for establishing electrical connection are disposed on the circuit surface 11a of the main die 11. In the connecting component disposing step, the connecting components 14 are appropriately disposed in regions of the circuit surface 11a of the main die 11 where the intermediate dies 12 are not to be disposed. In the connecting component disposing step, the connecting components 14 are disposed in a region to overlap with the intermediate die 12 to be disposed astride the main die 11. In the present embodiment, the connecting component disposing step includes a main-side connecting component disposing step of disposing one of connection terminals on the circuit surface 11a of the main die 11, and a substrate-side connection terminal disposing step of disposing the other of the connection terminals on the one surface 10a of the package substrate 10. Specifically, the connecting component disposing step includes a main-side connecting step of disposing Cu pillars 141 on the circuit surface 11a of the main die 11, and a step of disposing Cu core balls 142 on the one surface 10a of the package substrate 10. The connecting component disposing step further includes a substrate-side connecting step of disposing Cu pillars 141 on the circuit surface 13a of the sub die 13.

In the intermediate die disposing step, the plurality of intermediate dies 12 are disposed over the circuit surface 11a of the main die 11 in a state in which their circuit surfaces 12a face the circuit surface 11a. In the intermediate die disposing step, for example, an IF-IP, a stacked SRAM, a coprocessor, a VRM, and a stacked DRAM are disposed. In the intermediate die disposing step, at least one intermediate die 12 is disposed such that its end portion protrudes from an end of the main die 11 in a direction intersecting with the thickness direction. In the present embodiment, in the intermediate die disposing step, the stacked DRAM is disposed such that it protrudes from the end of the main die 11 in the direction intersecting the thickness direction.

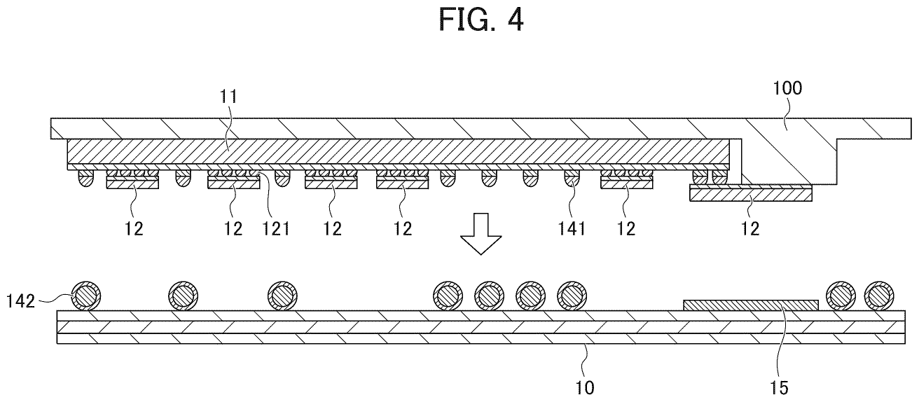

As illustrated in FIG. 4, in the relief layer disposing step, the relief layer 15 is disposed on the one surface 10a of the package substrate 10. In the relief layer disposing step, the relief layer 15 is disposed at a position on the one surface 10a of the package substrate 10 that corresponds in position to the intermediate die 12 to be disposed astride the main die 11 and the sub die 13.

In the package substrate disposing step, the one surface 10a of the package substrate 10 having, on the one surface 10a, the relief layer 15 for relieving stress at the position overlapping with the at least one intermediate die 12 is disposed such that the one surface 10a faces the main die 11 and the intermediate dies 12. In the package substrate disposing step, the relief layer 15 is brought into contact with the at least one intermediate die 12. Thereafter, in the package substrate disposing step, the Cu core balls 142 on the one surface 10a of the package substrate 10 and the Cu pillars 141 on the circuit surface 11a of the main die 11 are aligned with, and connected to, each other. In the package substrate disposing step, the mounting jig 100 is removed after the connection.

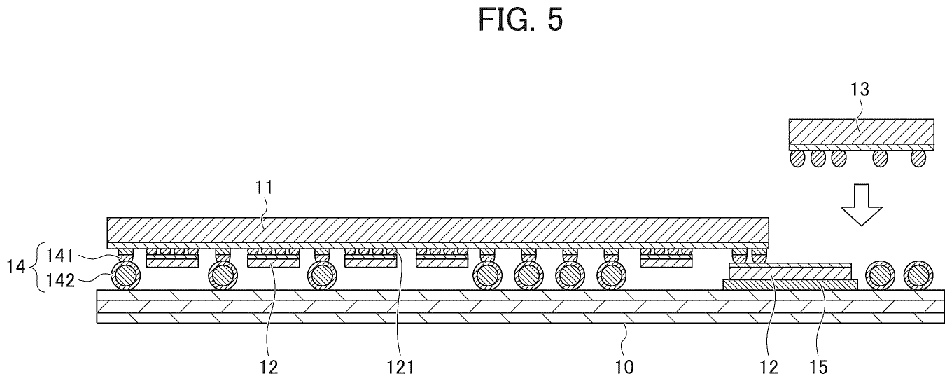

As illustrated in FIG. 5, in the sub die disposing step, the sub die 13 is disposed such that its circuit surface 13a faces the circuit surface 12a of the at least one intermediate die 12 and the one surface 10a of the package substrate 10. In the sub die disposing step, for example, the circuit surface 13a of the sub die 13 is positioned to face the circuit surface 12a of the intermediate die 12 protruding from the main die 11 in the direction intersecting the thickness direction. In the sub die disposing step, the solder balls 131 disposed on a region of the circuit surface 13a overlapping with the intermediate die 12 are connected to the circuit surface 12a of the intermediate die 12. In the sub die disposing step, the solder balls 131 disposed in a region of the circuit surface 13a not overlapping with the intermediate die 12 are connected to the Cu core balls 142 on the one surface 10a of the package substrate 10. Instead of the solder balls 131, Cu pillars 141 may be used. In the sub die disposing step, the underfill layer 16 (for example, an epoxy resin) is filled between the main die 11 and the package substrate 10 and between the sub die 13 and the package substrate 10.

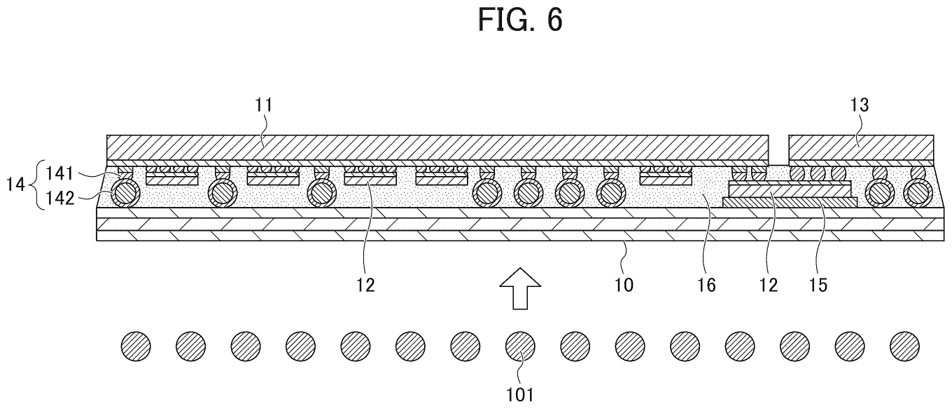

As illustrated in FIG. 6, in the solder ball disposing step, the solder balls 101 are disposed on the other surface 10b of the package substrate 10. In the solder ball disposing step, the solder balls 101 are disposed at positions to be electrically connected to the main substrate.

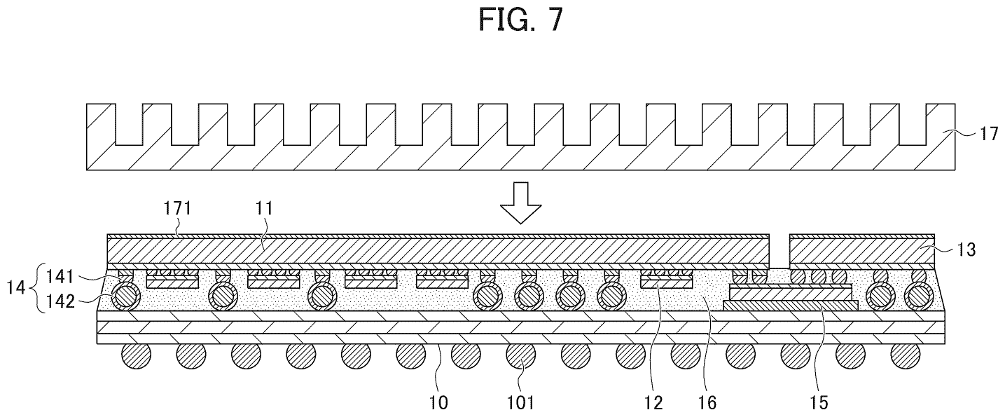

As illustrated in FIG. 7, in the heat dissipation fin disposing step, the heat dissipation fins 17 are disposed over the exposed surfaces 11b and 13b of the main die 11 and the sub die 13, which are opposite to the circuit surfaces of the main die 11 and the sub die 13. In the heat dissipation fin disposing step, the heat dissipation fins 17 are disposed via the TIM 171.

The module 1 and the method for manufacturing the module 1 according to the first embodiment exert the following effects.

(1) The module 1 includes a stack of a plurality of dies, and the package substrate 10. The stack includes the main die 11 having the circuit surface and disposed with the circuit surface facing the main surface of the package substrate 10, the plurality of intermediate dies 12 disposed between the package substrate 10 and the main die 11 and each having the circuit surface facing the circuit surface of the main die 11, the sub die 13 having the circuit surface and disposed with circuit surface facing the circuit surface of at least one intermediate die 12, and juxtaposed with the main die 11 in a direction intersecting with the thickness direction of the main die 11, and the connecting components 14 connecting the package substrate 10 to a region belonging to the circuit surface of the main die 11 and not overlapping with the intermediate dies 12 and a region belonging to the sub die 13 and not overlapping with the intermediate dies 12. The at least one intermediate die 12 is disposed astride an end portion of the circuit surface of the main die 11 and an end portion of the circuit surface of the sub die 13 in a state in which the circuit surface of the at least one intermediate die 12 faces the end portions. This configuration can reduce costs in comparison with a case where a substrate is provided between the package substrate 10 and the main die 11 and between the package substrate 10 and the sub die 13.

(2) The module 1 further includes the relief layer 15 disposed between the at least one intermediate die 12 and the package substrate 10 and configured to relieve stress between the package substrate 10 and the at least one intermediate die 12. With this configuration, in the case of using an intermediate die 12 that is so thick as to be likely to contact with the package substrate 10, the relief layer 15 can relieve stress generated in the intermediate die 12. Furthermore, in the case of using a plurality of intermediate dies 12 that is so thick as to be likely to contact with the package substrate 10, this configuration makes it possible to absorb variation in thicknesses of the intermediate dies 12, so that a high yield can be achieved.

(3) The sub die 13 is a power supply plate that supplies power to the intermediate die 12 disposed astride the main die 11 and the sub die 13. This configuration makes it possible to efficiently supply power to the main die 11 and the intermediate die 12.

(4) The method for manufacturing the module 1 including a stack of a plurality of dies includes: the connecting component disposing step including disposing the connecting components 14 for establishing electrical connection, on the circuit surface of the main die 11; the intermediate die disposing step including disposing the plurality of intermediate dies 12 over the circuit surface of the main die 11 such that their circuit surfaces face the circuit surface of the main die 11; the package substrate disposing step including disposing the package substrate 10 having, on its one surface, the relief layer 15 for relieving stress disposed at a position overlapping with at least one intermediate die 12 such that the one surface of the package substrate faces the main die 11 and the intermediate dies 12, and bringing the relief layer 15 into contact with the at least one intermediate die 12; and the sub die disposing step including disposing the sub die 13 such that its circuit surface faces the circuit surface of the at least one intermediate die 12 and the one surface of the package substrate 10. The intermediate die disposing step includes disposing the at least one intermediate die 12 such that an end portion of the at least one intermediate die 12 protrudes from an end of the main die 11 in a direction intersecting with the thickness direction. This method makes it possible to produce a package by simply disposing the package substrate 10 over the main die 11 and the sub die 13, thereby contributing to a low cost. Furthermore, in the case of using an intermediate die 12 that is so thick as to be likely to contact with the package substrate 10, provision of the relief layer 15 makes it possible to relieve the stress generated in the intermediate die 12. Furthermore, in the case of using a plurality of intermediate dies 12 that is so thick as to be likely to contact with the package substrate 10, this method makes it possible to absorb variation in thicknesses of the intermediate dies 12, so that high yield can be achieved.

(5) The connecting component disposing step includes a main-side connecting component disposing step of disposing one connection terminal on the circuit surface of the main die 11, and a substrate-side connection terminal disposing step of disposing the other connection terminal on the one surface of the package substrate 10. Providing two separate connection terminals and connecting them make it possible to achieve a high yield by absorbing variation in heights while forming high connecting components 14.

### Second Embodiment

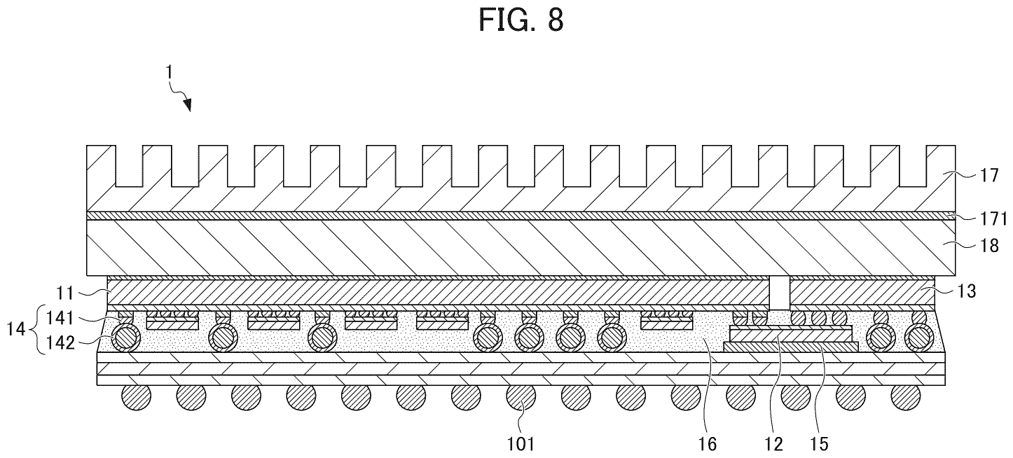

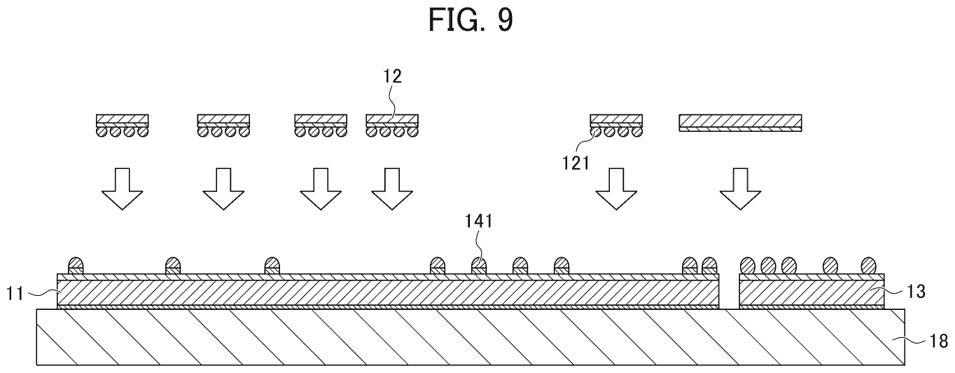

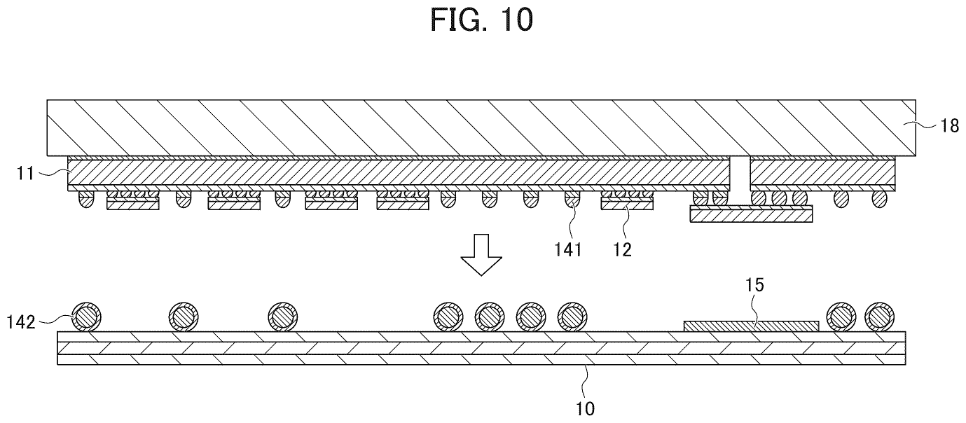

Next, a module 1 and a method for manufacturing the module 1 according to a second embodiment of the present invention will be described with reference to FIGS. 8 to 10. In the following description of the second embodiment, the same components as those of the above-described embodiment are denoted by the same reference numerals, and the description thereof is simplified or omitted. As illustrated in FIG. 8, the module 1 and the method for manufacturing the module 1 according to the second embodiment are different from those of the first embodiment in that the second embodiment includes a base plate 18 that is disposed between a main die 11 and heat dissipation fins 17 and between a sub die 13 and the heat dissipation fins 17. The base plate 18 is, for example, a metal plate or the like. Furthermore, as illustrated in FIG. 9, the module 1 and the method for manufacturing the module 1 according to the second embodiment are different from those of the first embodiment in that the base plate 18 is used instead of the mounting jig 100. In addition, the module 1 and the method for manufacturing the module 1 according to the second embodiment are different from those of the first embodiment in that according to the second embodiment, the sub die 13 is disposed on the base plate 18 together with the main die 11. According to the module 1 and the method for manufacturing the module 1 according to the second embodiment, after the main die 11, the sub die 13, and the intermediate dies 12 are disposed over the base plate 18 as illustrated in FIG. 9, the base plate 18 is vertically reversed to be brought into the state illustrated in FIG. 10, and then is aligned with, and disposed over, a package substrate 10 having thereon Cu core balls 142 and a relief layer 15. As a result, the main die 11, the sub die 13, and the intermediate dies 12, which remain disposed over the base plate 18, can be modularized into the module 1, whereby handleability during manufacturing can be improved.

### Third Embodiment

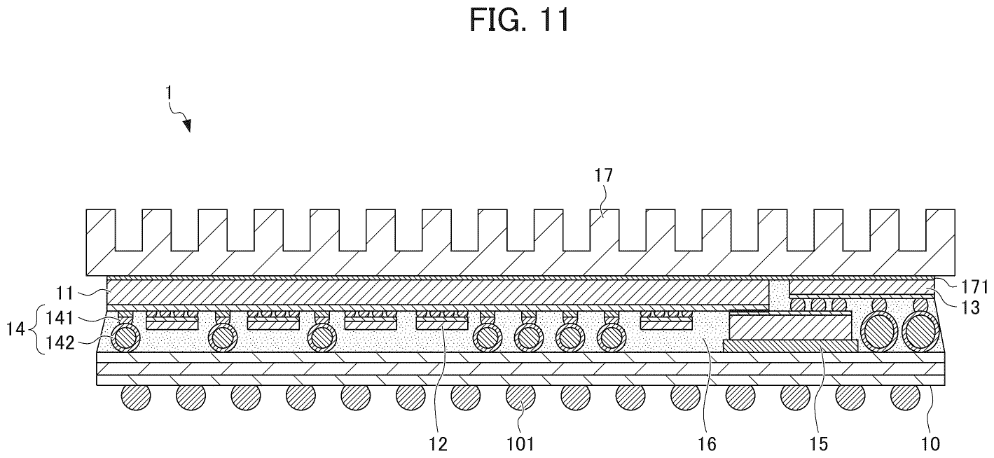

Next, a module 1 and a method for manufacturing the module 1 according to a third embodiment of the present invention will be described with reference to FIG. 11. In the following description of the third embodiment, the same components as those of the above-described embodiments are denoted by the same reference numerals, and the description thereof is simplified or omitted. The module 1 and the method for manufacturing the module 1 according to the third embodiment are different from those of the first and second embodiments in that according to the third embodiment, an intermediate die 12 disposed astride a main die 11 and a sub die 13 is connected to the main die 11 via bump-less bonding. The intermediate die 12 disposed astride the main die 11 and the sub die 13 communicates with the main die 11 by means of hybrid bonding or noncontact communication means (magnetic coupling communication (TCI), electric coupling communication, etc.).

(6) According to the module 1 and the method for manufacturing the module 1 of the third embodiment, in a case where the intermediate die 12 disposed astride the main die 11 and the sub die 13 communicates with the main die 11 with a high bandwidth, like a stacked DRAM, the hybrid bonding allows for a higher bandwidth because the hybrid bonding can be provided at a higher density than the Cu pillars 141. Furthermore, since using the noncontact communication means eliminates the need for the Cu pillars 141, the yield can be increased and the cost can be reduced.

### Fourth Embodiment

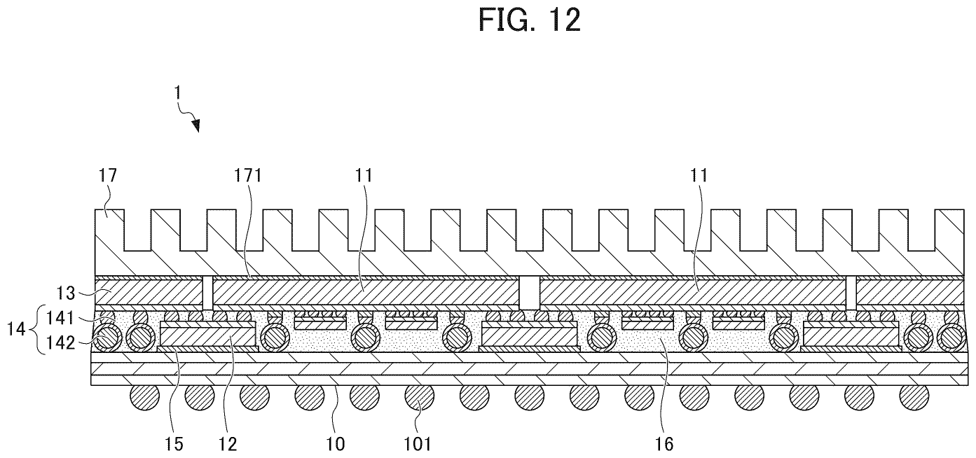

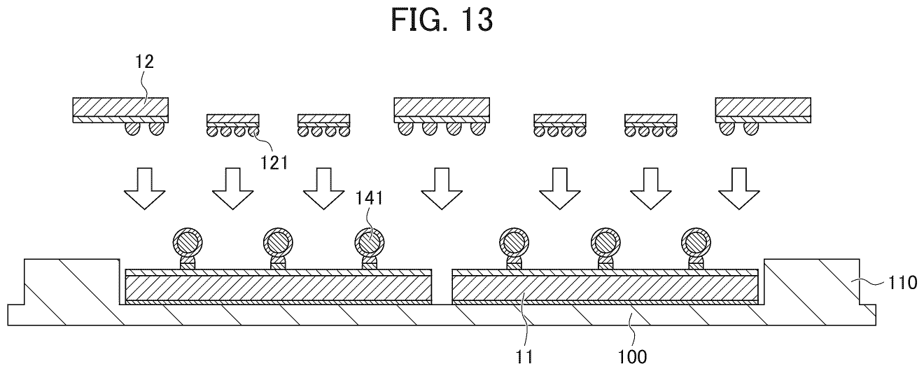

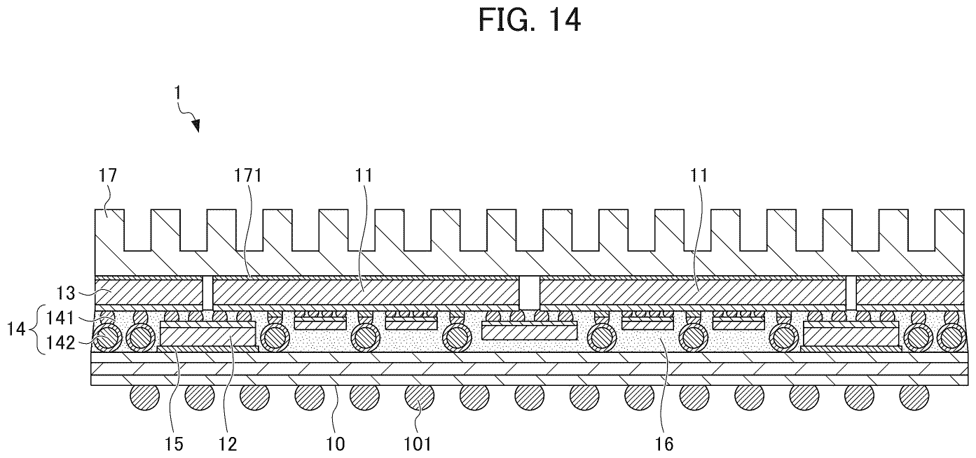

Next, a module 1 and a method for manufacturing the module 1 according to a fourth embodiment of the present invention will be described with reference to FIGS. 12 to 14. In the following description of the fourth embodiment, the same components as those of the above-described embodiments are denoted by the same reference numerals, and the description thereof is simplified or omitted. As illustrated in FIG. 12, the module 1 and the method for manufacturing the module 1 according to the fourth embodiment are different from those of the first to third embodiments in that the module 1 of the fourth embodiment includes two main dies 11 and two sub dies 13. Furthermore, the module 1 and the method for manufacturing the module 1 according to the fourth embodiment are different from those of the first to third embodiments in that the module 1 of the fourth embodiment includes one intermediate die 12 disposed astride the main dies 11. Moreover, as illustrated in FIG. 13, the module 1 and the method for manufacturing the module 1 according to the fourth embodiment are different from those of the first to third embodiments in that in a main die disposing step of the fourth embodiment, the two main dies 11 are disposed on a mounting jig 100 having two pedestal portions 110. In this way, the module 1 in which the sub die 13 and the intermediate die 12 are arranged with respect to each of two or more main dies 11 can be manufactured. As shown in FIG. 14, in a case where the surface opposite to the circuit surface 12a of the intermediate die 12 disposed astride the two main dies 11 is sufficiently separated from one surface 10a of the package substrate 10, the relief layer 15 may be omitted.

### Fifth Embodiment

Next, a module 1 and a method for manufacturing the module 1 according to a fifth embodiment of the present invention will be described with reference to FIG. 15. In the following description of the fifth embodiment, the same components as those of the above-described embodiments are denoted by the same reference numerals, and the description thereof is simplified or omitted. The module 1 and the method for manufacturing the module 1 according to the fifth embodiment are different from those of the first to fourth embodiments in that according to the fifth embodiment, a circuit surface 11a of a main die 11 includes, in a region adjacent to a region connected to an intermediate die 12, a power supply circuit 111 that stabilizes a voltage of power to be supplied to the intermediate die 12 by boosting or lowering the voltage. At the position connected to the intermediate die 12, the power supply circuit 111 stabilizes the power by boosting or stepping down the power that decreases or increases. The power supply circuit 111 measures, for example, a voltage value of the power to be supplied to the intermediate die 12, and boosts or steps down the voltage of the power based on a difference between the measured voltage value and a predetermined voltage value. For example, the power supply circuit 111 boosts or steps down the voltage so as to reduce a largest difference between the voltage values of power to be supplied to the intermediate die 12. A configuration is conceivable in which the intermediate die 12 is configured as a power supply module DRM that supplies power.

(7) The circuit surface 11a of the main die 11 includes, in its region adjacent to a region connected to the intermediate die 12, the power supply circuit 111 that boosts or steps down the voltage of power to be supplied to the intermediate die 12. This configuration makes it possible to stabilize the operation of the intermediate die 12.

### Sixth Embodiment

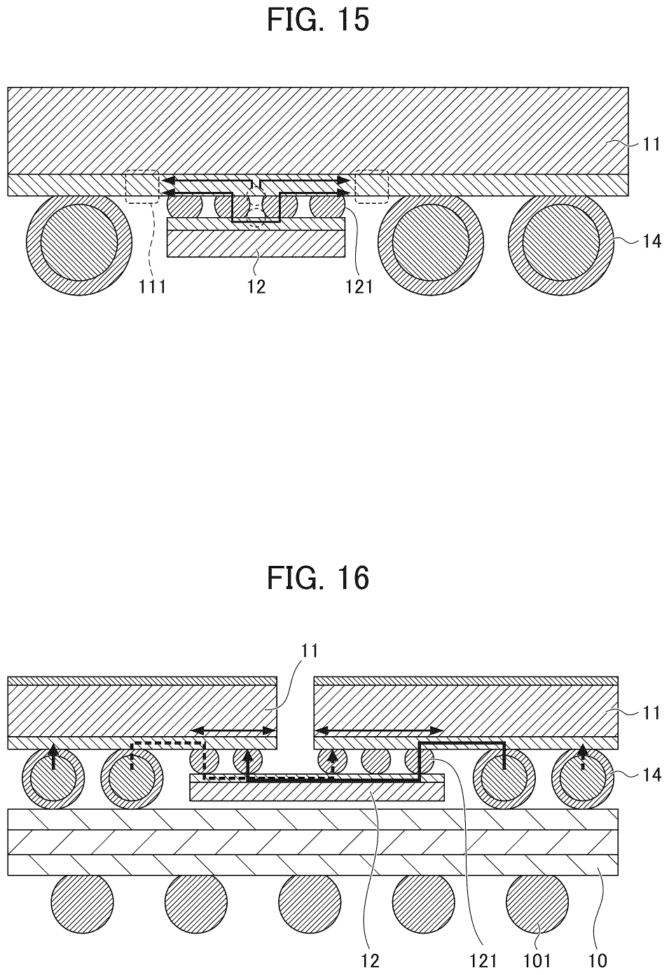

Next, a module 1 and a method for manufacturing the module 1 according to a sixth embodiment of the present invention will be described with reference to FIG. 16. In the following description of the sixth embodiment, the same components as those of the above-described embodiments are denoted by the same reference numerals, and the description thereof is simplified or omitted. The module 1 and the method for manufacturing the module 1 according to the sixth embodiment are different from those of the fourth and fifth embodiments in that, according to the sixth embodiment, part of the connecting components 14 for two main dies 11 serve as connecting components 14 for power supply: specifically, a connecting component 14 for power supply to one of the main dies 11 and a connecting component 14 for power supply to the other are provided to each main die 11. An intermediate die 12 (for example, a bridge chip) disposed astride the two main dies 11 differs from those of the fourth and fifth embodiments in that the intermediate die 12 of the sixth embodiment relays power supply between the two main dies 11. This configuration allows one of the two main dies 11 to receive, at its end, power supplied from the other of the two main dies 11 and vice versa, thereby contributing to reduction in wiring resistance.

It should be noted that the present invention is not limited to the above-described preferred embodiments of the module and the method for manufacturing the module, and modifications can be made to the present invention as appropriate.

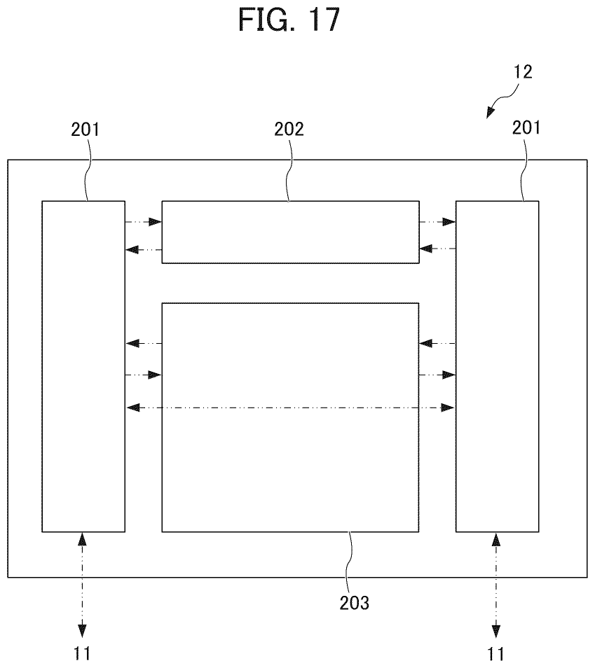

For example, in the fourth embodiment, the intermediate die 12 disposed astride the two main dies 11 may be a memory die that relays communication between the two main dies 11. As illustrated in FIG. 17, for example, the memory die preferably includes a plurality of interface circuits 201 as interfaces between the memory die and the main dies 11, a control and arbitration circuit 202, and a memory 203 (a memory control circuit and a memory array). In the memory die, there may be a path for the plurality of interface circuits 201 to access the memory 203 (the memory control circuit and the memory array), or there may be a path for the interface circuits 201 to directly transmit and receive data therebetween without intervention of the memory 203 (the memory control circuit and the memory array). Furthermore, based on control information inputted from the interface circuits 201, the control and arbitration circuit 202 preferably arbitrates reading and writing of data from and to the memory 203 (the memory control circuit and the memory array) that are performed by the plurality of interface circuits 201, and controls communication between the interface circuits 201.

In the fourth embodiment, the intermediate die 12 disposed astride the two main dies 11 may be a stacked memory in which a logic die and a memory die are stacked.

Preferably, the plurality of main dies 11 are arranged via the intermediate dies 12, which is disposed astride the two main dies 11, in a one-dimensional direction or a two-dimensional direction in a plan view.

This configuration allows for adopting various methods for the interface circuit 201 of an intermediate die to access the memory 203 (the memory control circuit and the memory array) belonging to the same intermediate die or various methods for the interface circuit 201 to communicate with an interface circuit 201 belonging to another intermediate die. For example, in a memory space common to all memory arrays in the plurality of intermediate dies 12, addresses may be assigned to the memory arrays. In a case where access to a memory array not belonging to an intermediate die 12 of interest is detected, access information indicating the address and a control signal may be forwarded to the interface circuits 201 of all of the other intermediate dies 12 in the module 1.

In a case where data transmission/reception is in packet format, dedicated addresses may be assigned to the memory arrays in all the intermediate dies 12. The address of a memory array connected to a circuit farther from the interface circuit 201 may be stored in each intermediate die 12. During communication, a target memory array is designated by a packet header. Upon receiving a packet, the intermediate die 12 preferably determines whether access is made to its own memory array or data is transmitted to or received from an intermediate die 12 as the destination of forwarding. At this time, control information relating to the memory access, such as the memory array address to be accessed and reading/writing, may be embedded in a payload portion.

Furthermore, a modified distributed memory system may be employed in which a plurality of adjacent main dies 11 exclusively share a memory array included in an intermediate die 12 commonly connected to the plurality of adjacent main dies 11. In this configuration, the memory array in the intermediate die 12 may be used as a buffer memory connecting the main dies 11 to each other or a FIFO.

For example, in the fourth embodiment, the main die 11 and the intermediate die 12 protruding in the direction intersecting with the thickness direction from the main die 11 may be connected to each other via bump-less bonding, as in the third embodiment.

Although the package substrate 10 is disposed with respect to the main die 11 set on the mounting jig 100 in the above embodiments, the present invention is not limited thereto. Conversely, the main die 11 set on the mounting jig 100 may be disposed with respect to the package substrate 10.

Although the intermediate die 12 is described as a stacked memory (stacked DRAM) in the above embodiments, the present invention is not limited thereto. Any of the main die 11, the intermediate die 12, and the sub die 13 may be a stacked memory.

### EXPLANATION OF REFERENCE NUMERALS

1: Module
10: Package substrate
11: Main die
12: Intermediate die
13: Sub die
14: Connecting component
15: Relief layer
16: Underfill layer
17: Heat dissipation fin
18: Base plate
100: Mounting jig
101: Solder ball
110: Pedestal portion
111: Power supply circuit
121: Micro-bump
131: Solder ball
141: Cu pillar
142: Cu core ball

1. A module comprising:
A module comprising:
a stack of a plurality of dies; and
a package substrate,
the stack comprising
a main die having a circuit surface and disposed with the circuit surface facing a main surface of the package substrate,
two intermediate dies disposed between the package substrate and the main die, each of the two intermediate dies having a circuit surface facing the circuit surface of the main die,
a sub die having a circuit surface and disposed with the circuit surface facing the circuit surface of one intermediate die of the two intermediate dies, the sub die being juxtaposed with the main die in a direction intersecting with a thickness direction of the main die, and
a connecting component electrically connecting the package substrate to a region of the circuit surface of the main die and a region of the circuit surface of the sub die, the regions not overlapping with the intermediate dies, wherein
an other intermediate die of the two intermediate dies is disposed in a state in which an entirety of the circuit surface of the other intermediate die faces the circuit surface of the main die, and
the one intermediate die is disposed astride an end portion of the circuit surface of the main die and an end portion of the circuit surface of the sub die in a state in which the circuit surface of the one intermediate die faces the end portions.

2. (canceled)

3. The module according to claim 1, wherein
the connecting component has a multilayer connection structure.

4. The module according to claim 1, wherein
any one of the main die, the intermediate die, and the sub die is a stacked memory.

5. The module according to claim 1, wherein
the circuit surface of the main die includes, in a region adjacent to a region connected to the intermediate die, a power supply circuit that boosts or steps down a voltage of power to be supplied to the intermediate die.

6. (canceled)

7. The module according to claim 1, wherein
the sub die is a power supply plate that supplies power to the one intermediate die disposed astride the main die and sub die.

8. A method for manufacturing a module including a stack of a plurality of dies, the method comprising:
disposing a main die on a mounting jig having a pedestal portion protruding from a position where an intermediate die to be disposed astride an end portion of the main die is placed;
disposing a connecting component configured to establish electrical connection, on a circuit surface of the main die;
disposing a plurality of the intermediate dies over the circuit surface of the main die such that circuit surfaces of the intermediate dies face the circuit surface of the main die;
disposing a package substrate such that one surface of the package substrate faces the main die and the intermediate dies; and
disposing a sub die such that a circuit surface of the sub die faces the circuit surface of at least one intermediate die of the intermediate dies and the one surface of the package substrate, wherein
in the disposing the intermediate dies, the at least one intermediate die is disposed such that an end portion of the at least one intermediate die protrudes from an end of the main die in a direction intersecting with a thickness direction.

9. The method according to claim 8, wherein
the disposing the connecting component includes disposing one connection terminal on the circuit surface of the main die, and
disposing an other connection terminal on the one surface of the package substrate.

10. The module according to claim 1, wherein
the one intermediate die disposed astride the main die and the sub die is a bridge that relays communication between the main die and the sub die.

11. The module according to claim 1, wherein
the one intermediate die disposed astride the main die and the sub die is a stacked memory in which a logic die and a memory die are stacked.

12. The module according to claim 1, wherein
the main die and the sub die are arranged in a one-dimensional direction or a two-dimensional direction in a plan view, via the one intermediate die disposed astride the main die and the sub die.

13. The module according to claim 12, wherein
the sub dies are a plurality of stacked memories including memory arrays, and the memory arrays are assigned with addresses in a common memory space.

14. The module according to claim 1, wherein
the other intermediate die disposed with the entirety of the circuit surface facing the main die is a voltage stabilization module.

15. A module comprising:
a stack of a plurality of dies; and
a package substrate,
the stack comprising
two main dies each having a circuit surface and each disposed with the circuit surface facing a main surface of the package substrate,
first to third intermediate dies disposed between the package substrate and the main dies and each having a circuit surface facing at least one of the circuit surfaces of the main dies, and
a connecting component electrically connecting the package substrate to regions of the circuit surfaces of the main dies, the regions not overlapping with the first to third intermediate dies, wherein
each of the second and third intermediate dies is disposed in a state in which an entirety of the circuit surface faces a respective one of the circuit surfaces of the main dies, and
the first intermediate die is disposed astride an end portion of the circuit surface of one main die of the two main dies and an end portion of the circuit surface of an other main die of the two main dies in a state in which the circuit surface of the first intermediate die faces the end portions.

16. The module according to claim 15, further comprising:
fourth and fifth intermediate dies disposed between the package substrate and the main dies and each having a circuit surface facing a respective one of the circuit surfaces of the main dies; and
two sub dies each having a circuit surface and each disposed with the circuit surface facing a respective one of the circuit surfaces of the fourth and fifth intermediate dies, the two sub dies being juxtaposed with the main dies in a direction intersecting with a thickness direction of the main dies, wherein
the fourth intermediate die is disposed astride an end portion of the circuit surface of the one main die of the two main dies and an end portion of the circuit surface of one sub die of the two sub dies in a state in which the circuit surface of the fourth intermediate die faces the end portions, and
the fifth intermediate die is disposed astride an end portion of the circuit surface of the other main die of the two main dies and an end portion of the circuit surface of an other sub die of the two sub dies in a state in which the circuit surface of the fifth die faces the end portions.

17. The module according to claim 15, wherein
the first intermediate die disposed astride the one main die and the other main die is a bridge that relays communication between the one main die and the other main die.

18. The module according to claim 16, wherein
the fourth intermediate die disposed astride the one main die and the one sub die is a bridge that relays communication between the one main die and the one sub die, and
the fifth intermediate die disposed astride the other main die and the other sub die is a bridge that relays communication between the other main die and the other sub die.

19. The module according to claim 16, wherein
the main dies are each a processor, and the sub dies are each a stacked memory.

20. The module according to claim 15, wherein
each of the second and third intermediate dies disposed in the state in which the entirety of the circuit surface faces the respective one of the circuit surfaces of the main dies is a voltage stabilization module.

21. The module according to claim 16, wherein
the main dies and the sub dies are arranged in a one-dimensional direction or a two-dimensional direction in a plan view, via the first intermediate die disposed astride the main dies or at least one of the fourth intermediate die disposed astride the one main die and the one sub die or the fifth intermediate die disposed astride the other main die and the other sub die.
